(19) United States
(12) Patent Application Publication
(10) Pub. No.: US 2013/0032476 A1
(43) Pub. Date: Feb. 7, 2013

(54) ROTARY CATHODES FOR MAGNETRON SPUTTERING SYSTEM

(71) Applicants: Daniel Theodore Crowley, Owatonna, MN (US); Michelle Lynn Neal, Albert Lea, MN (US)

(72) Inventors: Daniel Theodore Crowley, Owatonna, MN (US); Michelle Lynn Neal, Albert Lea, MN (US)

(73) Assignee: Sputtering Components, Inc., Owatonna, MN (US)

(21) Appl. No.: 13/562,698

(22) Filed: Jul. 31, 2012

Related U.S. Application Data
(60) Provisional application No. 61/515,094, filed on Aug. 4, 2011.

(51) Int. Cl. C23C 14/35

(52) U.S. Cl. 204/298.12; 204/298.16

(57) ABSTRACT

A magnetron sputtering device includes a cathode source assembly, and a target assembly removably coupled to the cathode source assembly. The cathode source assembly comprises a rotatable drive shaft, and a water feed tube located in the drive shaft and coupled to a tube support. The target assembly comprises a rotary cathode including a rotatable target cylinder, the rotary cathode removably mounted to the drive shaft. A magnet bar inside of the target cylinder is coupled to an end portion of the feed tube. A sweeping mechanism coupled to the magnet bar includes a control motor. An indexing pulley is coupled to the control motor, and a magnet bar pulley is coupled to the indexing pulley. The magnet bar pulley is affixed to the tube support such that any motion of the magnet bar pulley is translated to the magnet bar through the tube support and the feed tube.

### CROSS-REFERENCE TO RELATED APPLICATIONS

This application claims the benefit of U.S. Provisional Patent Application Ser. No. 61/515,094, filed on Aug. 4, 2011, which is herein incorporated by reference.

### BACKGROUND

Magnetron sputtering of rotating targets is used extensively for producing a wide variety of thin films on substrates. In magnetron sputtering, the material to be sputtered is either formed in the shape of a cylinder or is adhered to the outer surface of a cylindrical support tube made of a rigid material. A magnetron assembly is disposed within the tube and supplies magnetic flux which permeates the target such that there is significant magnetic flux at the outer surface of the target. The magnetic field is designed in a way such that it retains electrons emitted from the target such as to increase the probability that they will have ionizing collisions with a working gas, hence enhancing the efficiency of the sputtering process.

Suitably uniform thin films generally cannot be achieved over large areas by using standard rotating cylindrical cathodes when the substrate and the sputtering magnetron are both held static relative to each other. This is due to the structure of the magnetic field, which usually forms two (sometimes four) lines of high intensity sputtering plasma that are substantially parallel to the major axis of the cathode. The sputtered material leaves the target with two approximately Gaussian distributions (one from each line of high intensity sputtering) and arrives at the substrate with similar distributions. The final thickness of the film is a superposition of the two (Gaussian) distributions. When multiple cathodes are used, the film thickness will be the sum of multiple such distributions.

The typical magnetron assembly for rotating cathodes comprises three substantially parallel rows of magnets attached to a yoke of magnetically conductive material, such as steel, that helps complete the magnetic circuit. The direction of magnetization of the magnets will be radial with respect to the major axis of the sputtering target. The center row will have the opposite polarity of the two outer rows.

Magnetic flux of the inner and outer rows of magnets is linked through the magnetically conductive yoke, on one side of the magnets. On the other side of the magnets, opposite the yoke, the magnetic flux is not contained in a magnetically conductive material; hence, it permeates substantially unimpeded through the target which is substantially non-magnetic. Thus, two arc-shaped magnetic fields are provided at and above the working surface of the target. This provides the two lines of high intensity sputtering plasma, discussed above. Additionally, the outer rows are slightly longer that the inner row and additional magnets, of the same polarity as the outer rows, are place at the ends of the assembly between the two outer rows creating the so-called “turn-around” areas of the drift path. This has the effect of connecting the two drift paths, hence forming one continuous ovular “racetrack” drift path. This optimizes the retention of the electrons and therefore optimizes the efficiency of the sputtering process. Attempts to coat a static substrate using an array of the above configured sources will result in a uniformity profile that is unacceptable for most applications. Such a uniformity profile is shown in FIG. 6, which is discussed further hereafter.

Standard approaches can yield acceptable film uniformity for a static system. Nevertheless, since the total film thickness is a sum of multiple Gaussian-type distributions of material flux, there will still be some amount of periodic film thickness variation (ripple) across the substrate dimension that is normal to the major axis of the cathode. This ripple in the film thickness may not be acceptable for some products. In these cases, mechanisms have been developed to sweep the magnet field over a portion of the target circumference. Sweeping the magnet array during operation causes the magnetic field of the magnet array to move over a portion of a cathode target circumference, thereby reducing film ripple.

Conventional sputtering systems that provide a sweeping magnetic field do so either with a constant angular velocity between two positions that are positioned symmetrically about the line of symmetry, or by discrete steps between two positions. Although these methods may reduce film thickness ripple, they may not necessarily optimize the film uniformity. The reason for this is that both methods are using linear compensation to modify non-linear distributions.

### SUMMARY

A magnetron sputtering device includes a cathode source assembly, and a cathode target assembly removably coupled to the cathode source assembly. The cathode source assembly comprises a rotatable drive shaft, and a water feed tube located in the rotatable drive shaft and coupled to a tube support at an outer end of the cathode source assembly. The cathode target assembly comprises a rotary cathode including a rotatable target cylinder, the rotary cathode removably mounted to the rotatable drive shaft. A magnet bar inside of the target cylinder is coupled to an end portion of the water feed tube. A sweep mechanism is coupled to the magnet bar and includes a control motor. An indexing pulley is operatively coupled to the control motor, and a magnet bar pulley is coupled to the indexing pulley by a belt. The magnet bar pulley is affixed to the tube support such that any motion of the magnet bar pulley is translated to the magnet bar through the tube support and the water feed tube. The sweep mechanism imparts a predetermined motion to the magnet bar during sputtering that is independent of target cylinder rotation.

### BRIEF DESCRIPTION OF THE DRAWINGS

Features of the present invention will become apparent to those skilled in the art from the following description with reference to the drawings. Understanding that the drawings depict only typical embodiments of the invention and are not therefore to be considered limiting in scope, the invention will be described with additional specificity and detail through the use of the accompanying drawings, in which:

FIGS. 1A is a side view of magnetron sputtering device with a rotary cathode according to one embodiment;

FIG. 1B is a cross-sectional side view of the magnetron sputtering device of FIG. 1A;

FIG. 2A is a front view of a magnetron sputtering system with rotary cathodes according to one embodiment;

FIG. 2B is a rear view of the magnetron sputtering system of FIG. 2A;

FIG. 3A is a bottom view of the magnetron sputtering system of FIG. 2A;

FIG. 3B is a bottom perspective view of the magnetron sputtering system of FIG. 2A;

FIG. 4A is a perspective view of a magnetron sputtering system with rotary cathodes according to another embodiment;

FIG. 4B is a bottom view of the magnetron sputtering system of FIG. 4A;

FIG. 5A is a side view of a magnetron sputtering device with a rotary cathode according to an alternative embodiment;

FIG. 5B is a cross-sectional side view of the magnetron sputtering device of FIGS. 5A;

FIG. 6 is a schematic diagram showing an end view of two standard rotary cathodes with conventional magnetrons; and

FIG. 7 is a schematic diagram showing an end view of two rotary cathodes with optimized magnetrons according to one embodiment.

### DETAILED DESCRIPTION

In the following detailed description, embodiments are described in sufficient detail to enable those skilled in the art to practice the invention. It is to be understood that other embodiments may be utilized without departing from the scope of the present invention. The following description is, therefore, not to be taken in a limiting sense.

A rotary cathode for a magnetron sputtering device is provided that produces substantially uniform thin films over large area substrates. A sweep mechanism is configured to independently move a magnet array inside of the rotary cathode during sputtering operations. A plurality of rotary cathodes can be implemented in a magnetron sputtering system for depositing uniform films over large area substrates that remain static with respect to the cathodes.

During operation of the magnetron sputtering device, motion is transferred from a control motor to a magnetron assembly inside a rotary cathode. In one implementation, a sweeping action can be controlled by a variable driver, such as a servo motor, which can be programmed to provide a desired movement. The magnetron assembly is moved relative to a line of symmetry.

Prior conventional systems that use a sweeping magnetic field do so either with a constant angular velocity between two positions, which are positioned symmetrically about the line of symmetry, or by discrete steps between two positions. Although these methods may reduce film thickness ripple, they may not necessarily optimize the film uniformity. The reason for this is that both methods are using linear compensation to modify non-linear distributions. To truly optimize the uniformity, a non-constant sweeping motion can be used.

In a sputtering system for coating one or more substrates in a substantially uniform manner, a plurality of magnetron sputtering devices, each with a rotary cathode, are arranged such that the rotary cathodes are substantially parallel to each other and at a substantially regular spacing. The cathodes are also disposed in a plane that is substantially parallel to one or more substrates to be coated. A magnetron within each rotary cathode is optimized with respect to a geometrical configuration of the sputtering system so as to provide a substantially uniform coating on the substrates when the substrates are placed in a static position relative to the magnetron sputtering devices. The arrangement of magnetron sputtering devices includes one or more outer magnetron sputtering devices at opposing ends, and one or more inner magnetron sputtering devices between the outer magnetron sputtering devices. Each of the magnetron sputtering devices can include a motorized mechanism operatively coupled to the magnetron to impart a sweeping motion to the magnetron that is independent of cathode rotation. The motorized mechanism can be driven by a controller that is programmed with various dithering patterns.

In another embodiment of a magnetron sputtering system with multiple cathodes, the outer most cathodes may have magnetron assemblies that are more like standard assemblies. If an optimized design is used on the outer most cathodes, then the outer most straight segments of the racetrack will sputter substantially away from the edge of the substrate, thereby having undesired affects. Furthermore, having the standard design on the outer most cathodes improves the uniformity at the ends because it compensates for the fall-off of overlapping flux distributions of the plurality of cathodes.

In another embodiment, the magnetron assemblies of the outer most cathodes can have a different design than the inner magnetrons, and thus have a different sweeping motion than that of the inner magnetrons. This further improves uniformity at the outer edges of the substrate. In principle, each magnetron can have a different design and/or different programmed motions as needed.

To modify a standard cathode design, which lacks the independent magnetron motion, would necessitate the addition of more rotary seals and rotary electrical contacts. This would result in undesirable complication that will result in greater opportunity for cathode failure and greater maintenance requirements. This increase in mechanical complication is mitigated in the present approach due to optimizing the magnetron design to suit the geometry of the coater apparatus. As such, the flexibility of the electric and cooling lines to compensate for the new motion can be utilized, thereby minimizing the increased mechanical complication.

The various features of the present magnetron sputtering devices and systems are described in further detail as follows with respect to the drawings.

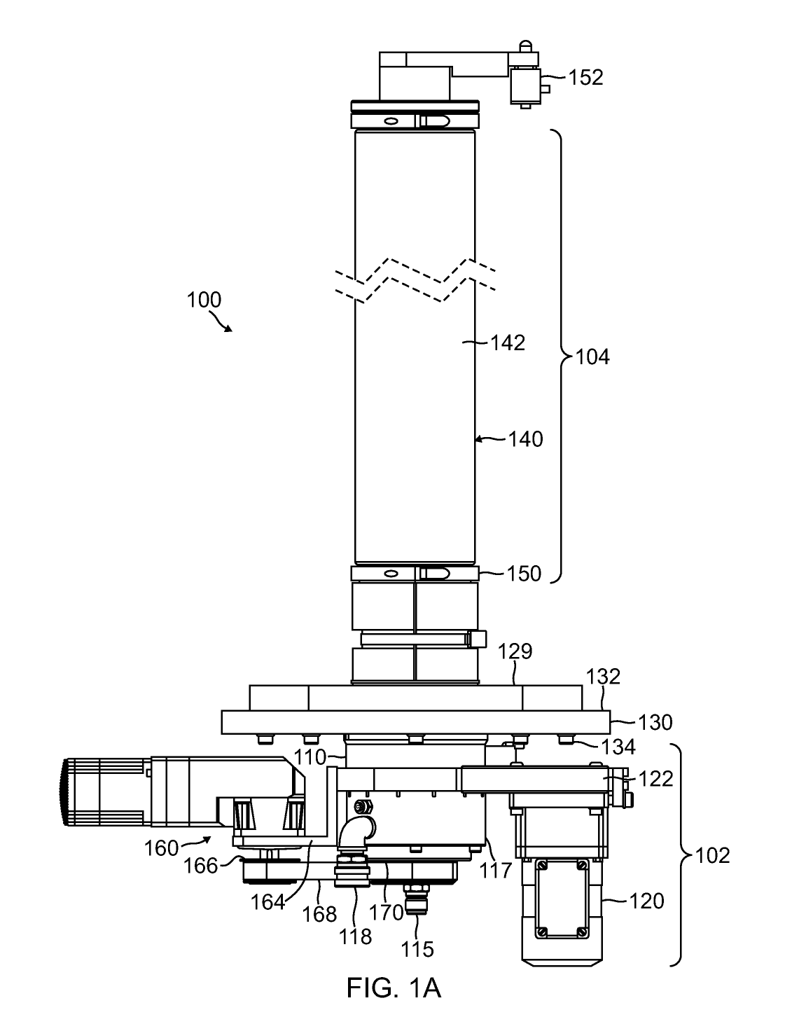

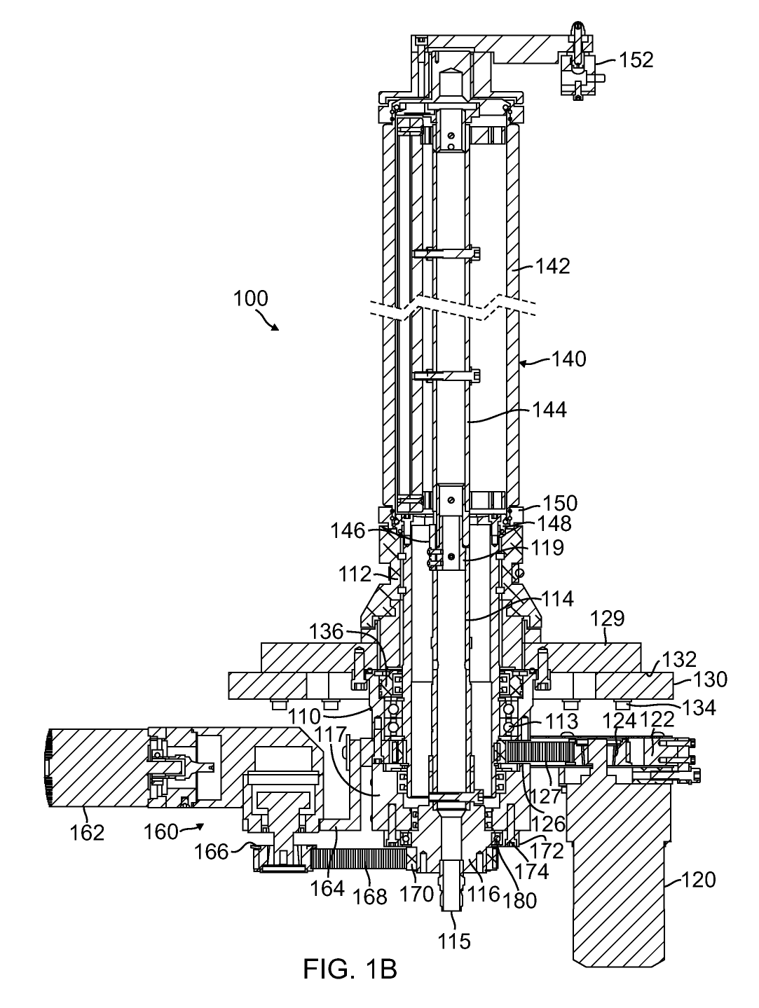

FIGS. 1A and 1B illustrate a magnetron sputtering device 100 according to one embodiment. The magnetron sputtering device 100 generally includes a cathode source assembly 102 and a cathode target assembly 104 that is removably coupled to the cathode source assembly 102, as depicted in FIG. 1A.

The cathode source assembly 102 includes a main housing 110 and a hollow drive shaft 112 inside of housing 110 as shown in FIG. 1B. One or more ball bearings 113 could possibly be only one bearing is located around drive shaft 112 within housing 110. A single end feed-thru in housing 110 is provided such that all utilities are introduced into the feed-thru.

A water feed tube 114 is located in drive shaft 112 and is coupled to a tube support 116 at an outer end of cathode source assembly 102. The water feed tube 114 is in fluid communication with a first fluid port 115 through tube support 116. A water seal housing 117 adjacent to tube support 116 is in fluid communication with a second fluid port 118 as shown in FIG. 1A. The fluid ports 115 and 118 are configured to couple with sources of water and air (not shown) when needed during operation of magnetron sputtering device 100. A distal end portion 119 of water feed tube 114 is located at an opposite end from tube support 116 as depicted in FIG. 1B.

A gear motor 120 is mounted to a drive housing 122, which surrounds a pulley 124 operatively coupled to gear motor 120 and a drive pulley 126. The pulley 124 and drive pulley 126 are rotatably coupled by a drive belt 127 for rotating drive shaft 112.

The drive shaft 112 protrudes from housing 110 into a vacuum coating chamber (not shown) enclosed by a chamber wall 130. A mounting flange 129 around housing 110 abuts against an inner surface 132 of chamber wall 130. The mounting flange 129 is secured to chamber wall 130 by a plurality of bolts 134. A vacuum seal assembly 136 surrounds a portion of housing 110 that extends through chamber wall 130 to maintain a vacuum seal, as shown in FIG. 1B.

The cathode target assembly 104 includes a rotary cathode 140, which has a rotatable target cylinder 142 with a target material on an outer surface thereof. A magnet bar 144 is supported inside of target cylinder 142 and is coupled to end portion 119 of water feed tube 114 including a magnet bar anti-rotation key 146. The rotary cathode 140 is removably mounted to an end portion of drive shaft 112 that protrudes into the vacuum coating chamber by a target mounting flange 148 and a target clamp 150. An optional outboard support member 152 can be affixed at a distal end of target cylinder 142 and secured to a vacuum chamber wall.

The magnetron sputtering device 100 also includes a magnet bar sweep mechanism 160 that provides for independent movement of magnet bar 144 during sputtering operations. The magnet bar sweep mechanism 160 imparts a predetermined motion to magnet bar 144 during sputtering operations that is independent of target cylinder rotation.

The magnet bar sweep mechanism 160 includes a control motor 162, such as a stepper motor or a servo motor, which is attached to housing 110 with a motor mount 164. The control motor can be configured such as by programming to produce varying dither patterns for moving magnet bar 144.

The motor 162 is operatively coupled to an indexing pulley 166, which supports a drive belt 168. The drive belt 168 is also supported by a magnet bar pulley 170 attached to a indexing bearing housing 172, which in turn is coupled to water seal housing 117 with a plurality of bolts 174. The drive belt 168 can be a timing belt, chain, or other device that connects pulleys 166 and 170 without slippage. For example, a typical timing belt is flat and includes teeth.

A bearing 180 is held by the stationary indexing bearing housing 172 and provides the ability to easily rotate the magnet bar assembly 114 while providing support for radial and thrust loads from the weight of the magnet bar 114 thru the tube support 116.

The cathode source assembly 102 is shown in a bottom-mounted position in FIG. 1A such that cathode target assembly 104 extends in an upwardly direction with a distal end of target cylinder 142 higher than a proximal end of target cylinder 142. The magnetron sputtering device 100 can also be mounted in other positions to provide for different cathode orientations. For example, the cathode source assembly 102 can be placed in a top-mounted position such that cathode target assembly 104 extends in a downwardly direction with the distal end of target cylinder 142 lower than the proximal end of target cylinder 142. Alternatively, cathode source assembly 102 can be placed in a side-mounted position such that cathode target assembly 104 has a substantially horizontal orientation.

A magnetron sputtering system can be implemented with a plurality of magnetron sputtering devices that correspond to the magnetron sputtering device 100 shown in FIG. 1A. For example, two or more magnetron sputtering devices can be arranged in a magnetron sputtering system to coat larger substrates.

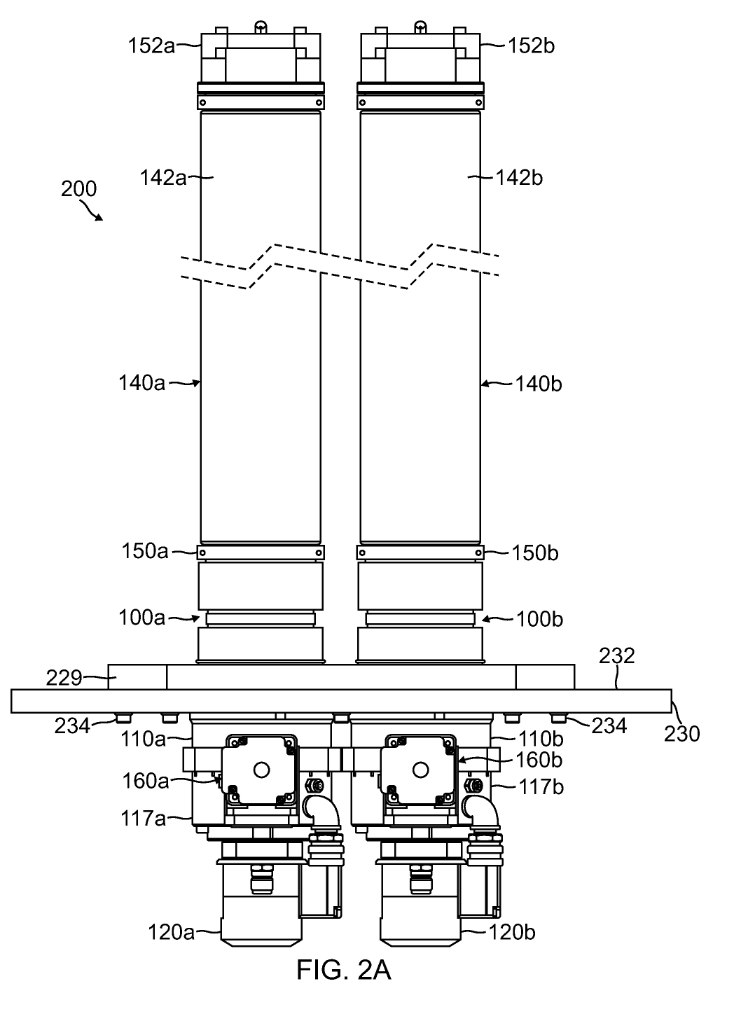

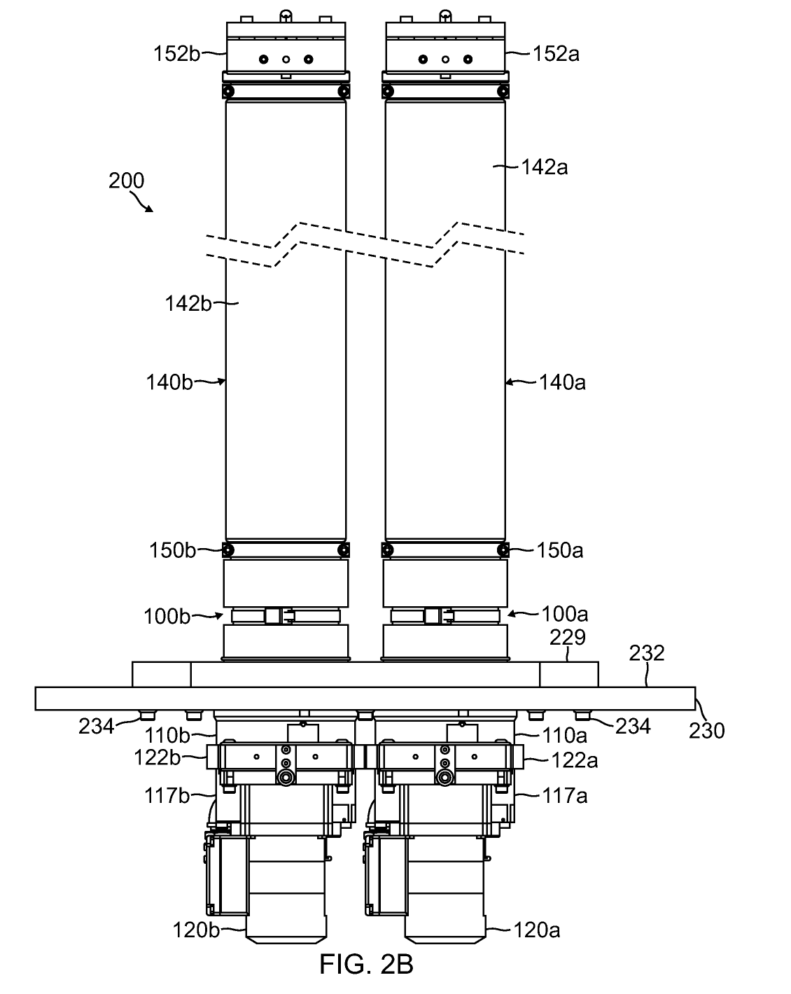

FIGS. 2A and 2B illustrate a magnetron sputtering system 200 according to one embodiment, which includes a pair of magnetron sputtering devices 100a and 100b. The magnetron sputtering devices 100a and 100b each have a respective main housing 110a, 110b and a respective water seal housing 117a, 117b. Each of magnetron sputtering devices 100a, 100b also include a respective gear motor 120a, 120b that is mounted to a respective drive housing 122a, 122b.

The magnetron sputtering devices 100a, 100b also have a respective rotary cathode 140a, 140b, each with a rotatable target cylinder 142a, 142b. A vacuum coating chamber (not shown) is enclosed by a chamber wall 230. Each of rotary cathodes 140a, 140b is removably mounted to an end portion of a drive shaft that protrudes into the vacuum coating chamber by a respective target clamp 150a, 150b. An optional outboard support member 152a, 152b can be affixed at a distal end of each target cylinder 142a, 142b and secured to a vacuum chamber wall.

In one embodiment, a common mounting flange 229 surrounds bottom mount housing 110a, 110b and abuts against an inner surface 232 of a chamber wall 230. The mounting flange 229 is secured to chamber wall 230 by a plurality of bolts 234. In an alternative embodiment, the cathodes can be mounted directly to the chamber wall without the common mounting flange.

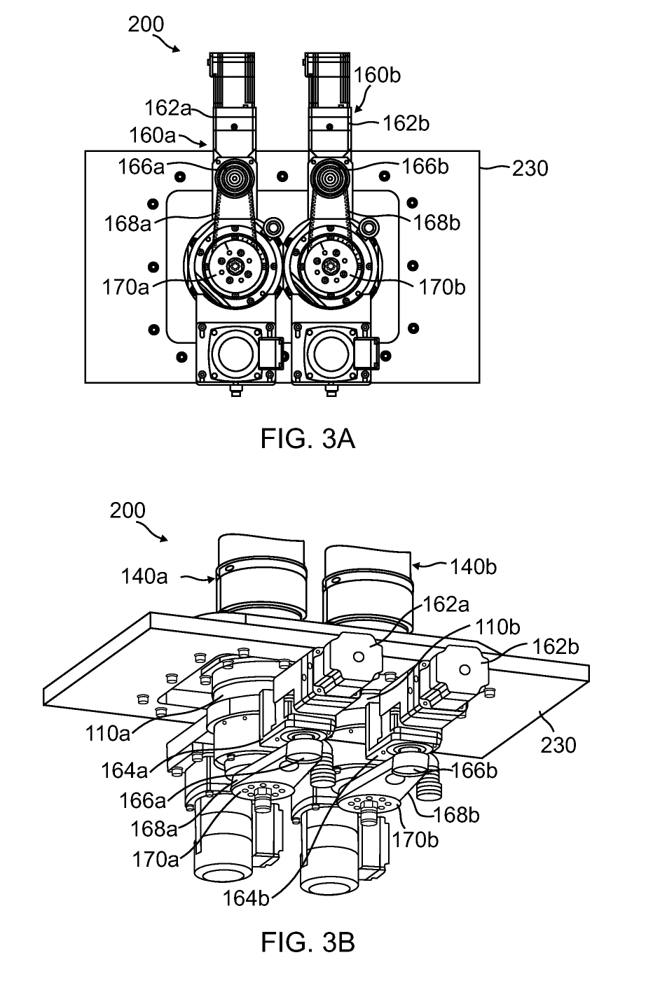

Each of magnetron sputtering devices 100a, 100b includes a respective magnet bar sweep mechanism 160a, 160b that provides for movement of the magnet bars in rotary cathodes 140a, 140b during sputtering operations. The magnet bar sweep mechanisms 160a, 160b are shown in more detail in FIGS. 3A and 3B.

The magnet bar sweep mechanisms 160a, 160b each include a respective control motor 162a, 162b attached to housing 110a, 110b with an indexing mount 164a, 164b. Each motor 162a, 162b is operatively coupled to respective indexing pulleys 166a and 166b, which support respective drive belts 168a, 168b. The belts 168a, 168b are each also supported by a respective magnet bar pulley 170a, 170b.

The magnet bar sweep mechanisms 160a, 160b operate in the same manner as described above for magnet bar sweep mechanism 160 described previously.

The rotary cathodes 140a, 140b are shown in a bottom-mounted position in FIGS. 2A and 2B such that target cylinders 142a, 142b extend in an upwardly or vertical direction, with a distal end of the target cylinders higher than a proximal end of the target cylinders. The magnetron sputtering system 200 can also be mounted in other positions to provide for different cathode orientations. For example, rotary cathodes 140a, 140b can be placed in a top-mounted position such that target cylinders 142a, 142b extend in a downwardly direction with the distal end of the target cylinders lower than the proximal end of the target cylinders. Alternatively, rotary cathodes 140a, 140b can be placed in a side-mounted position such that target cylinders 142a, 142b have a substantially horizontal orientation.

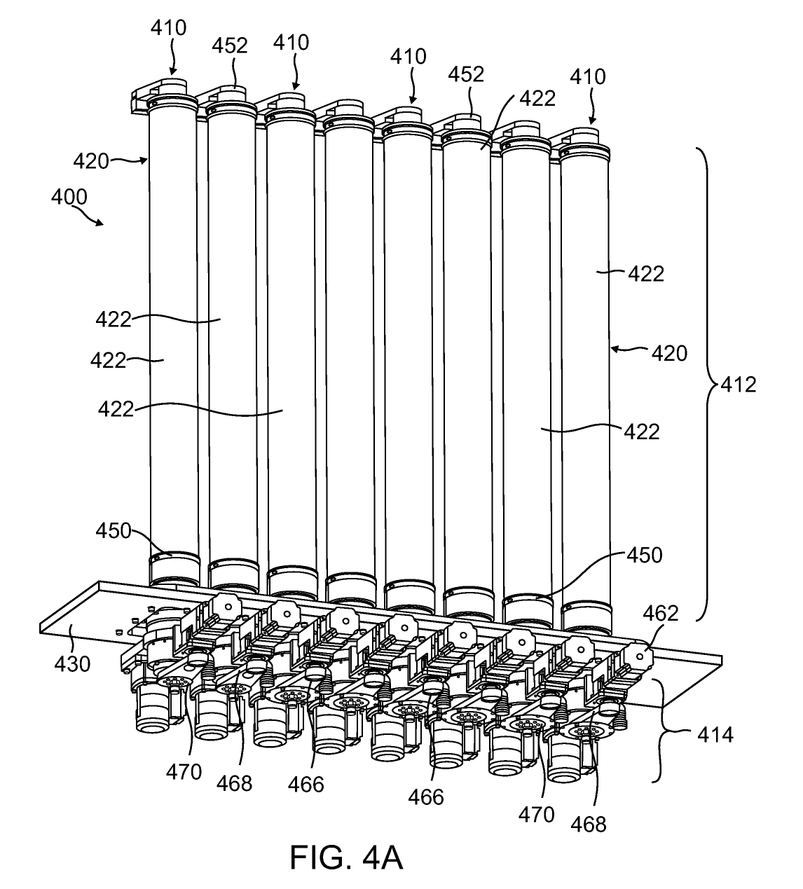

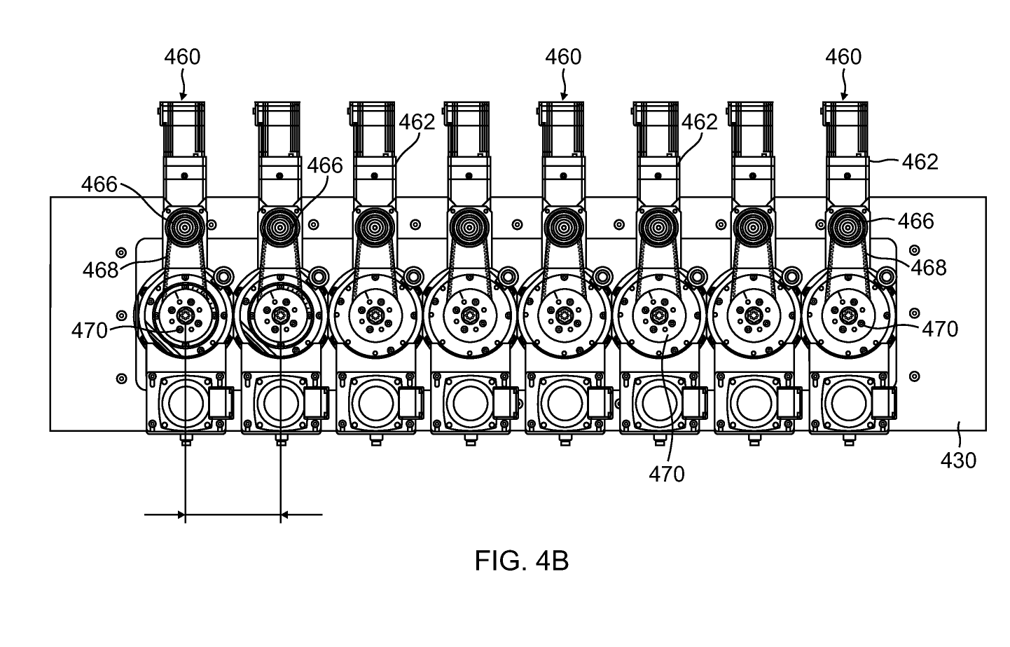

FIGS. 4A and 4B illustrate a magnetron sputtering system 400 according to another embodiment, which includes a plurality of magnetron sputtering devices 410. Although eight magnetron sputtering devices 410 are depicted, sputtering system 400 can be implemented with more or less magnetron sputtering devices 410.

The magnetron sputtering devices 410 each include essentially the same components as described previously for magnetron sputtering device 100 shown in FIG. 1A. According, magnetron sputtering devices 410 each generally include a cathode source assembly 412 and a cathode target assembly 414 that is removably coupled to the cathode source assembly 412, as depicted in FIG. 4A.

The magnetron sputtering devices 410 also have a respective rotary cathode 420, each with a rotatable target cylinder 422. A vacuum coating chamber (not shown) is enclosed by a chamber wall 430. Each of rotary cathodes 420 is removably mounted to an end portion of a drive shaft that protrudes into the vacuum coating chamber by a respective target clamp 450. The rotary cathodes 420 can be arranged substantially parallel to each other and at substantially regular spacing, with the rotary cathodes 420 disposed in a plane that is substantially parallel to a substrate to be coated in the vacuum coating chamber. An optional outboard support member 452 can be affixed at a distal end of each target cylinder 422 and secured to a vacuum chamber wall.

Each of magnetron sputtering devices 410 includes a respective magnet bar sweep mechanism 460 that provides for movement of the magnet bars in rotary cathodes 420 during sputtering operations. The magnet bar sweep mechanisms 460 each include a respective control motor 462 operatively coupled to a respective indexing pulley 466, which support a respective drive belt 468. Each drive belt 468 is also supported by a respective magnet bar pulley 470.

The magnet bar sweep mechanisms 460 operate in essentially the same manner as described above for magnet bar sweep mechanism 160 described previously.

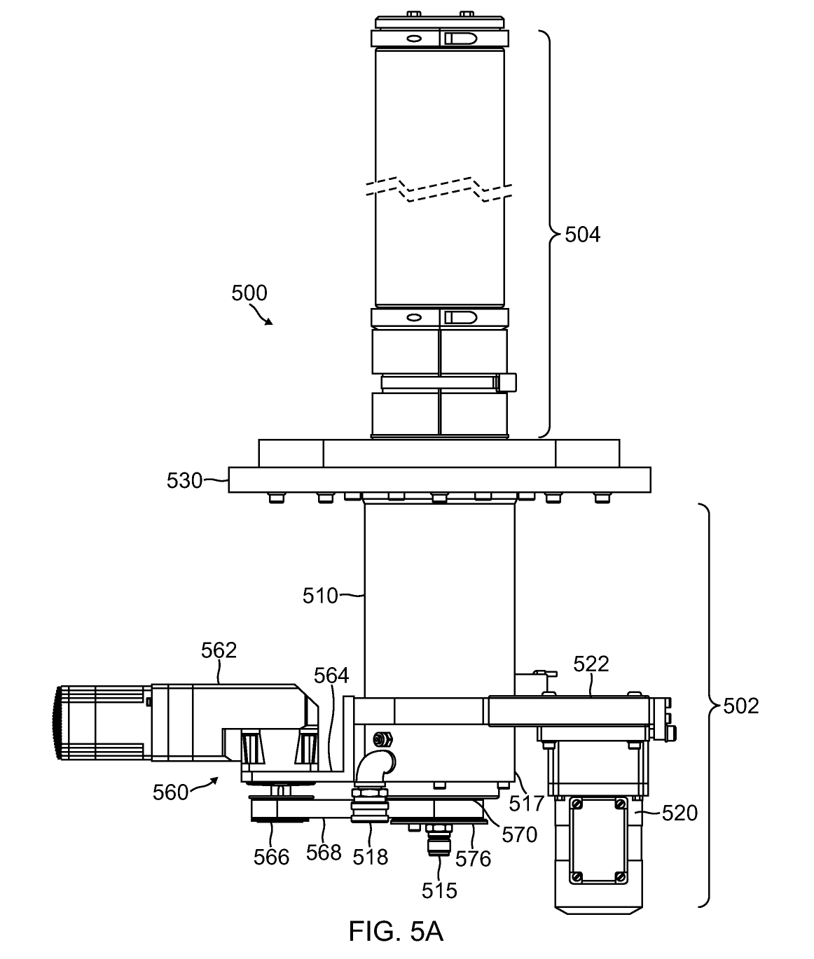

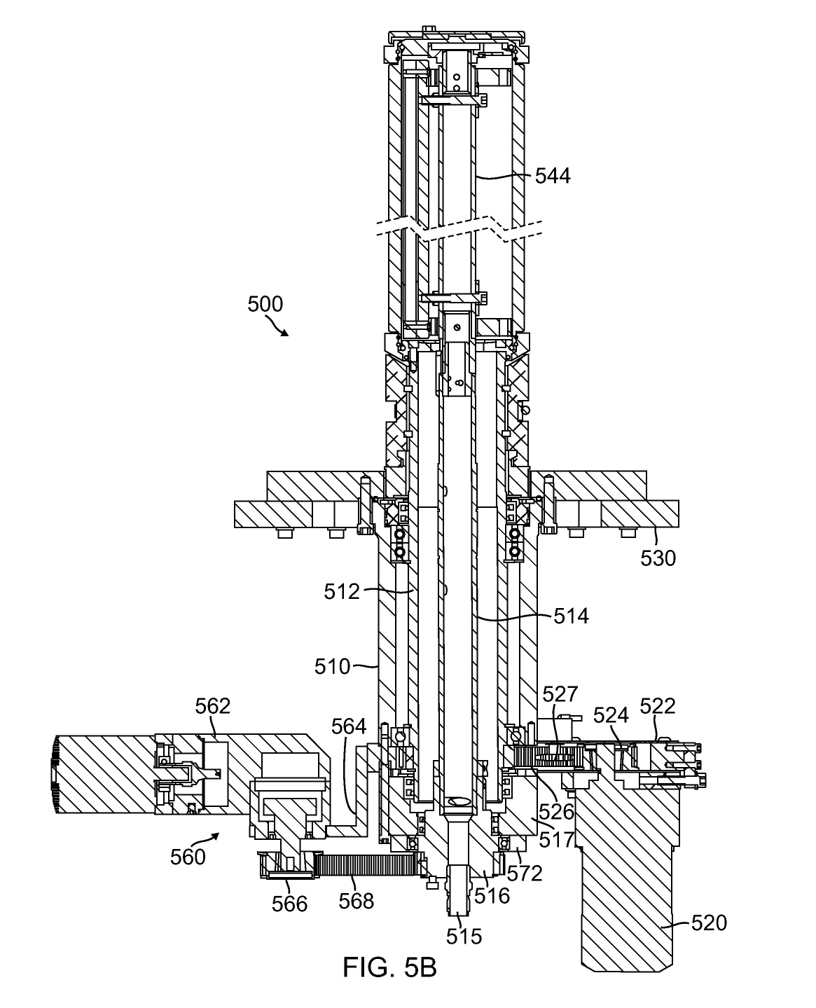

FIGS. 5A and 5B illustrate a magnetron sputtering device 500 according to a further embodiment. The magnetron sputtering device 500 generally includes a cathode source assembly 502 and a cathode target assembly 504 that is removably coupled to the cathode source assembly 502, as depicted in FIG. 5A.

The cathode source assembly 502 includes an elongated housing 510 and a hollow drive shaft 512 inside of housing 510 as shown in FIG. 5B. A water feed tube 514 is located in drive shaft 512 and is coupled to a tube support 516 at an outer end of cathode source assembly 502. The water feed tube 514 is in fluid communication with a first fluid port 515 through tube support 516. A water seal housing 517 adjacent to tube support 516 is in fluid communication with a second fluid port 518 as shown in FIG. 5A.

A gear motor 520 is mounted to a drive housing 522, which surrounds a pulley 524 operatively coupled to gear motor 520 and a drive pulley 526. The pulley 524 and drive pulley 526 are rotatably coupled by a drive belt 527 for rotating drive shaft 512. The drive shaft 512 protrudes from housing 510 into a vacuum coating chamber (not shown) enclosed by a chamber wall 530.

The cathode target assembly 504 includes a rotary cathode 540, which has a rotatable target cylinder 542 with a target material on an outer surface thereof. A magnet bar 544 is supported inside of target cylinder 542 and is coupled to water feed tube 514. The rotary cathode 540 is removably mounted to an end portion of drive shaft 512 that protrudes into the vacuum coating chamber.

The magnetron sputtering device 500 also includes a magnet bar sweep mechanism 560 that provides for movement of magnet bar 544 during sputtering operations. The magnet bar sweep mechanism 560 includes a control motor 562 attached to housing 510 with a motor mount 564. The motor 562 is operatively coupled to an indexing pulley 566, which supports a drive belt 568. The drive belt 568 is also supported by a magnet bar pulley 570 attached to an indexing bearing housing 572 The magnet bar sweep mechanism 560 operates in essentially the same manner as described above for magnet bar sweep mechanism 160 described previously.

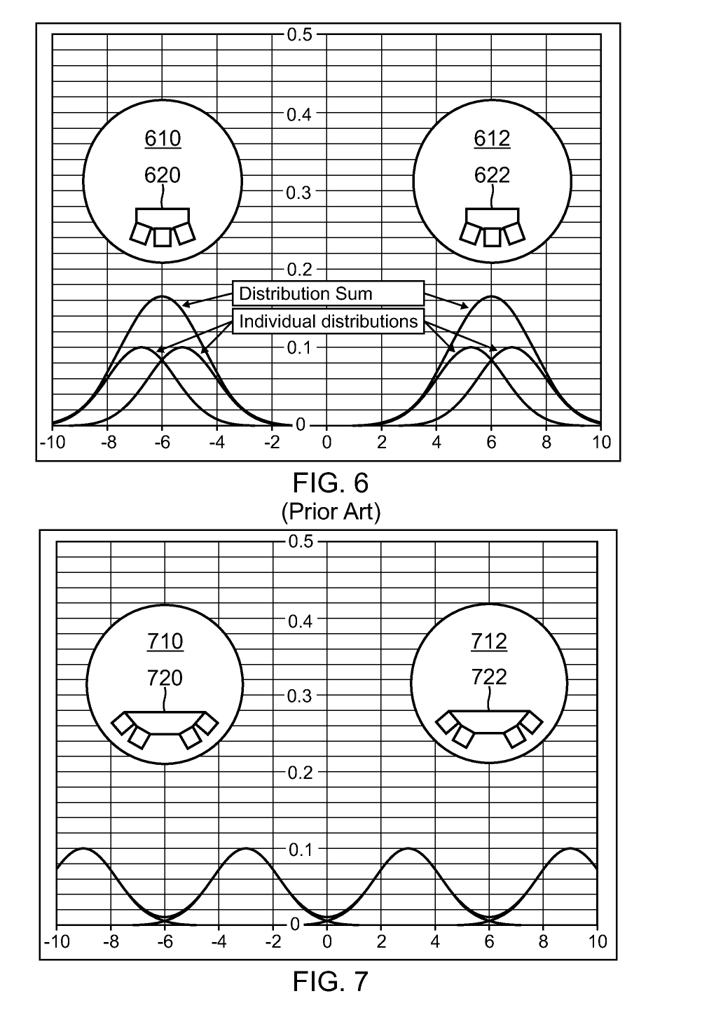

FIG. 6 is a schematic diagram showing an end view of two standard rotary cathodes 610 and 612, each with a respective magnetron configuration 620 and 622. Each magnetron configuration 620, 622 includes a center row of magnets 630 of a first polarity and a concentric oval of magnets 632 of a second polarity disposed around the center row of magnets. FIG. 6 also includes a graphical representation of the particle flux distributions for rotary cathodes 610 and 612, which includes a distribution sum and individual distributions for each cathode.

An improved approach for a magnetron provides two concentric ovals of magnets with an inner oval of a first polarity and an outer oval of a second polarity, as disclosed in U.S. application Ser. No. 13/344,871, filed on Jan. 6, 2012, the disclosure of which is incorporated by reference. In this way, the angular separation between the two linear portions of the “racetrack” can easily be adapted to provide the best possible uniformity that can be produced with the multitude of cathodes required for a particular coating system, while simultaneously minimizing the high angle material flux.

An example of the above improved approach is shown in FIG. 7, which depicts an end view of two rotary cathodes 710 and 712, each with a magnetron configuration 720 and 722 that is optimized. Each magnetron configuration 720, 722 includes an inner oval of magnets 730 of a first polarity and an outer oval of magnets 732 of a second polarity around the inner oval of magnets 730. FIG. 7 also includes a graphical representation of the particle flux distribution for rotary cathodes 710 and 712.

A comparison of the FIGS. 6 and 7 indicate that the thickness variation of a coating on a substrate can be reduced simply by changing the magnetron to an optimized design such as depicted for cathodes 710 and 712. The magnetron configurations 720 and 722 have a wider angular separation between racetrack portions than in magnetron configurations 620 and 622. The magnetron configurations 720 and 722 are one exemplary embodiment for reducing the amount of oscillation required to achieve coating uniformity.

Optimization will vary depending on overall system geometry, especially the distance between cathodes and the cathode to substrate distance. While optimization can be achieved through multiple trials, optimization can also be determined through mathematical formulas, which take into account geometrical values and a distribution function of the material flux. Formulae for flux distribution can be found in Sieck, Distribution of Sputtered Films from a C-Mag® Cylindrical Source, 38^{th} Annual Technical Conference Proceedings, Society of Vacuum Coaters, pp. 281-285 (1995), the disclosure of which is incorporated by reference.

In another embodiment of a magnetron sputtering system with multiple cathodes, the rotary cathodes in the outer magnetron sputtering devices can have magnetrons that are configured differently from the magnetrons in the rotary cathodes of the inner magnetron sputtering devices. For example, the rotary cathodes of the outer magnetron sputtering devices may have magnetrons that are like standard magnetrons such as the magnetron configurations of FIG. 6, while the magnetrons in the rotary cathodes of the inner magnetron sputtering devices can have magnetrons that are optimized such as the magnetron configurations of FIG. 7.

The present invention may be embodied in other specific forms without departing from its essential characteristics. The described embodiments are to be considered in all respects only as illustrative and not restrictive. The scope of the invention is therefore indicated by the appended claims rather than by the foregoing description. All changes that come within the meaning and range of equivalency of the claims are to be embraced within their scope.

What is claimed is:

1. A magnetron sputtering device, comprising:
a cathode source assembly, comprising:
a rotatable drive shaft; and
a water feed tube located in the rotatable drive shaft and coupled to a tube support at an outer end of the cathode source assembly;
a cathode target assembly removably coupled to the cathode source assembly, the cathode target assembly comprising:
a rotary cathode including a rotatable target cylinder, the rotary cathode removably mounted to the rotatable drive shaft; and
a magnet bar inside of the target cylinder and coupled to an end portion of the water feed tube;
a sweep mechanism operatively coupled to the magnet bar, the sweep mechanism comprising:
a control motor;
an indexing pulley operatively coupled to the control motor; and
a magnet bar pulley operatively coupled to the indexing pulley by a belt, the magnet bar pulley affixed to the tube support such that any motion of the magnet bar pulley is translated to the magnet bar through the tube support and the water feed tube;
wherein the sweep mechanism imparts a predetermined motion to the magnet bar during sputtering that is independent of target cylinder rotation.

2. The magnetron sputtering device of claim 1, wherein the control motor is configured to produce varying dither patterns for moving the magnet bar.

3. The magnetron sputtering device of claim 1, wherein the control motor comprises a stepper motor or a servo motor.

4. The magnetron sputtering device of claim 1, wherein the control motor is attached to the cathode source assembly with a motor mount.

5. The magnetron sputtering device of claim 1, wherein the magnet bar pulley is attached to an indexing bearing housing on the cathode source assembly.

6. The magnetron sputtering device of claim 1, wherein the cathode target assembly has a substantially vertical orientation when mounted in a vacuum chamber.

7. The magnetron sputtering device of claim 1, wherein the cathode target assembly has a substantially horizontal orientation when mounted in a vacuum chamber.

8. A magnetron sputtering system, comprising:
a vacuum coating chamber;
a plurality of magnetron sputtering devices, each of the magnetron sputtering devices comprising:
a cathode source assembly mounted to a wall of the vacuum coating chamber and comprising:
a rotatable drive shaft; and
a water feed tube located in the rotatable drive shaft and coupled to a tube support at an outer end of the cathode source assembly;
a cathode target assembly removably coupled to the cathode source assembly and disposed in the vacuum coating chamber, the cathode target assembly comprising:
a rotary cathode including a rotatable target cylinder, the rotary cathode removably mounted to the rotatable drive shaft; and
a magnet bar inside of the target cylinder and coupled to an end portion of the water feed tube; and
a sweep mechanism operatively coupled to the magnet bar, the sweep mechanism comprising:
a control motor;
an indexing pulley operatively coupled to the control motor; and
a magnet bar pulley operatively coupled to the indexing pulley by a belt, the magnet bar pulley affixed to the tube support such that any motion of the magnet bar pulley is translated to the magnet bar through the tube support and the water feed tube;
wherein the magnet bar sweep mechanism imparts a predetermined motion to the magnet bar during sputtering that is independent of target cylinder rotation;
wherein the rotary cathodes are arranged substantially parallel to each other and at substantially regular spacing, the rotary cathodes disposed in a plane that is substantially parallel to a substrate to be coated in the vacuum chamber.

9. The magnetron sputtering system of claim 8, wherein the control motor is configured to produce varying dither patterns for moving the magnet bar.

10. The magnetron sputtering system of claim 8, wherein the control motor comprises a stepper motor or a servo motor.

11. The magnetron sputtering system of claim 8, wherein the control motor is attached to the cathode source assembly with a motor mount.

12. The magnetron sputtering system of claim 8, wherein the magnet bar pulley is attached to an indexing bearing housing on the cathode source assembly.

13. The magnetron sputtering system of claim 8, wherein each cathode target assembly has a substantially vertical orientation in the vacuum chamber.

14. The magnetron sputtering system of claim 8, wherein each cathode target assembly has a substantially horizontal orientation in the vacuum chamber.

15. A sputtering system for coating one or more substrates in a substantially uniform manner, comprising:
a plurality of magnetron sputtering devices each with a rotary cathode, the magnetron sputtering devices arranged such that the rotary cathodes are substantially parallel to each other and at a substantially regular spacing, the cathodes also disposed in a plane that is substantially parallel to one or more substrates to be coated; and
a magnetron within each rotary cathode that is optimized with respect to a geometrical configuration of the sputtering system so as to provide a substantially uniform coating on the substrates when the substrates are placed in a static position relative to the magnetron sputtering devices;
wherein the arrangement of magnetron sputtering devices includes one or more outer magnetron sputtering devices at opposing ends, and one or more inner magnetron sputtering devices between the outer magnetron sputtering devices.

16. The system of claim 15, wherein the rotary cathodes in the outer magnetron sputtering devices have magnetrons that are configured differently from the magnetrons in the rotary cathodes of the inner magnetron sputtering devices.

17. The system of claim 15, wherein each magnetron sputtering device has a motorized mechanism operatively coupled to the magnetron to impart a sweeping motion to the magnetron that is independent of cathode rotation.

18. The system of claim 17, where the motorized mechanism is driven by a controller that is programmed with various dithering patterns.
